(19) United States
(12) Patent Application Publication
(10) Pub. No.: US 2015/0263275 A1
(43) Pub. Date: Sep. 17, 2015

(54) MANUFACTURING METHOD OF MAGNETIC MEMORY DEVICE AND MANUFACTURING APPARATUS OF MAGNETIC MEMORY DEVICE

(71) Applicant: Kazuhiro TOMIOKA, Seoul (KR)

(72) Inventor: Kazuhiro TOMIOKA, Seoul (KR)

(21) Appl. No.: 14/481,817

(22) Filed: Sep. 9, 2014

Related U.S. Application Data
(60) Provisional application No. 61/952,037, filed on Mar. 12, 2014.

(51) Int. Cl. H01L 43/12; H01L 21/67; H01J 37/32

(52) U.S. Cl. CPC H01L 43/12; H01J 37/32899; H01L 21/67069

(57) ABSTRACT

According to one embodiment, a method of manufacturing a magnetic memory device, includes etching at least a part of a stacked film including a magnetic layer, to form a columnar structure, and performing a surface treatment on a side surface of the columnar structure, using a surface treatment gas containing a predetermined element and hydrogen.

### CROSS-REFERENCE TO RELATED APPLICATIONS

This application claims the benefit of U.S. Provisional Application No. 61/952,037, filed Mar. 12, 2014, the entire contents of which are incorporated herein by reference.

### FIELD

Embodiments described herein relate generally to a method of manufacturing a magnetic memory device, and an apparatus for manufacturing the magnetic memory device.

### BACKGROUND

A magnetic memory device with magnetic elements formed on a semiconductor substrate has been proposed. As the magnetic elements, magnetoresistive effect elements are used, for example.

The magnetic elements are formed by etching a stacked film including magnetic layers to thereby form a columnar structure. However, the side surface of the columnar structure formed by etching does not always exhibit an appropriate surface state. Unless the side surface exhibits an appropriate surface state, the characteristics and/or reliability of the resultant magnetic memory device may be degraded.

There is a demand for a magnetic memory device manufacturing method capable of making the side surface of the columnar structure including the magnetic layer to have an appropriate surface state.

### BRIEF DESCRIPTION OF THE DRAWINGS

FIG. 1 is a schematic view showing the configuration of an apparatus for manufacturing magnetic memory devices according to embodiments;

FIG. 2 is a schematic cross-sectional view showing a part of a method of manufacturing a magnetic memory device according to a first embodiment;

FIG. 3 is a schematic cross-sectional view showing a part of the method of manufacturing the magnetic memory device according to the first embodiment;

FIG. 4 is a schematic cross-sectional view showing a part of the method of manufacturing the magnetic memory device according to the first embodiment;

FIG. 5 is a schematic cross-sectional view showing a part of the method of manufacturing the magnetic memory device according to the first embodiment;

FIG. 6 is a schematic cross-sectional view showing a part of a method of manufacturing a magnetic memory device according to a modification of the first embodiment;

FIG. 7 is a schematic cross-sectional view showing a part of a method of manufacturing a magnetic memory device according to a second embodiment;

FIG. 8 is a schematic cross-sectional view showing a part of the method of manufacturing the magnetic memory device according to the second embodiment;

FIG. 9 is a schematic cross-sectional view showing a part of the method of manufacturing the magnetic memory device according to the second embodiment;

FIG. 10 is a schematic cross-sectional view showing a part of the method of manufacturing the magnetic memory device according to the second embodiment;

FIG. 11 is a schematic cross-sectional view showing a part of the method of manufacturing the magnetic memory device according to the second embodiment;

FIG. 12 is a schematic cross-sectional view showing a part of the method of manufacturing the magnetic memory device according to the second embodiment;

FIG. 13 is a schematic cross-sectional view showing a part of a method of manufacturing a magnetic memory device according to a third embodiment;

FIG. 14 is a schematic cross-sectional view showing a part of the method of manufacturing the magnetic memory device according to the third embodiment;

FIG. 15 is a schematic cross-sectional view showing a part of the method of manufacturing the magnetic memory device according to the third embodiment;

FIG. 16 is a schematic cross-sectional view showing a part of the method of manufacturing the magnetic memory device according to the third embodiment;

FIG. 17 is a schematic cross-sectional view showing a part of the method of manufacturing the magnetic memory device according to the third embodiment; and

FIG. 18 is a schematic cross-sectional view showing a part of the method of manufacturing the magnetic memory device according to the third embodiment.

### DETAILED DESCRIPTION

In general, according to one embodiment, a method of manufacturing a magnetic memory device, includes: etching at least a part of a stacked film including a magnetic layer, to form a columnar structure; and performing a surface treatment on a side surface of the columnar structure, using a surface treatment gas containing a predetermined element and hydrogen.

The embodiments will be described with reference to the accompanying drawings.

(Apparatus Configuration)

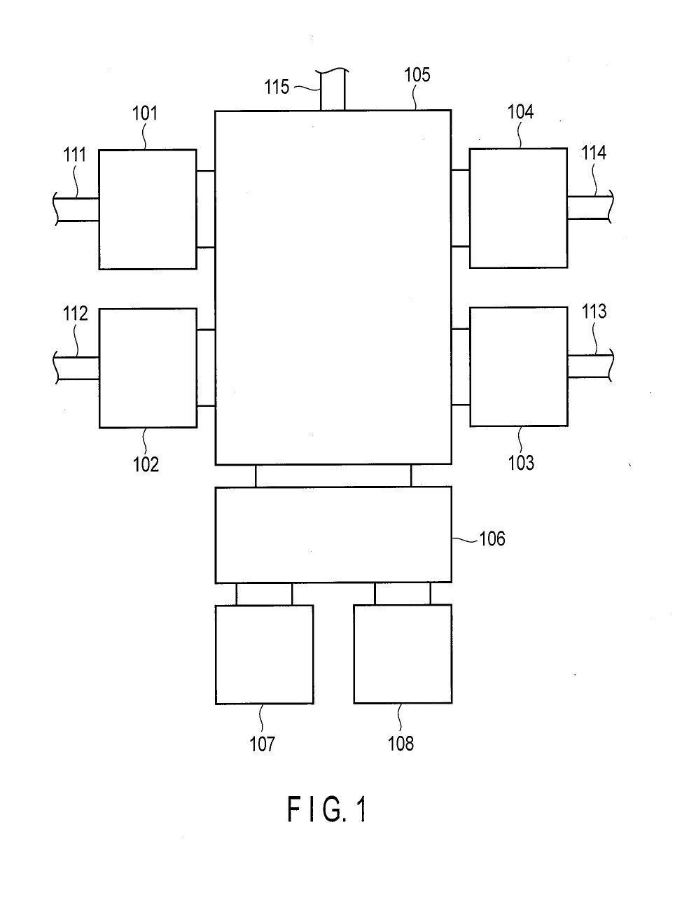

FIG. 1 is a schematic view showing the configuration of an apparatus for manufacturing magnetic memory devices according to embodiments.

The apparatus shown in FIG. 1 comprises an etching chamber 101 for reactive ion etching (RIE), an etching chamber 102 for ion beam etching (IBE), a surface treatment chamber 103 for surface treatment, a deposition chamber 104 for deposition, a transfer chamber 105 for transfer, a load lock 106, a load port 107, and a load port 108. One of the etching chambers 101 and 102 may not be provided.

An etching gas supply section 111, an etching gas supply section 112, a surface treatment gas supply section 113, a deposition gas supply section 114 and a purge gas supply section 115 are connected to the etching chamber 101, the etching chamber 102, the surface treatment chamber 103, the deposition chamber 104 and the transfer chamber 105, respectively.

### First Embodiment

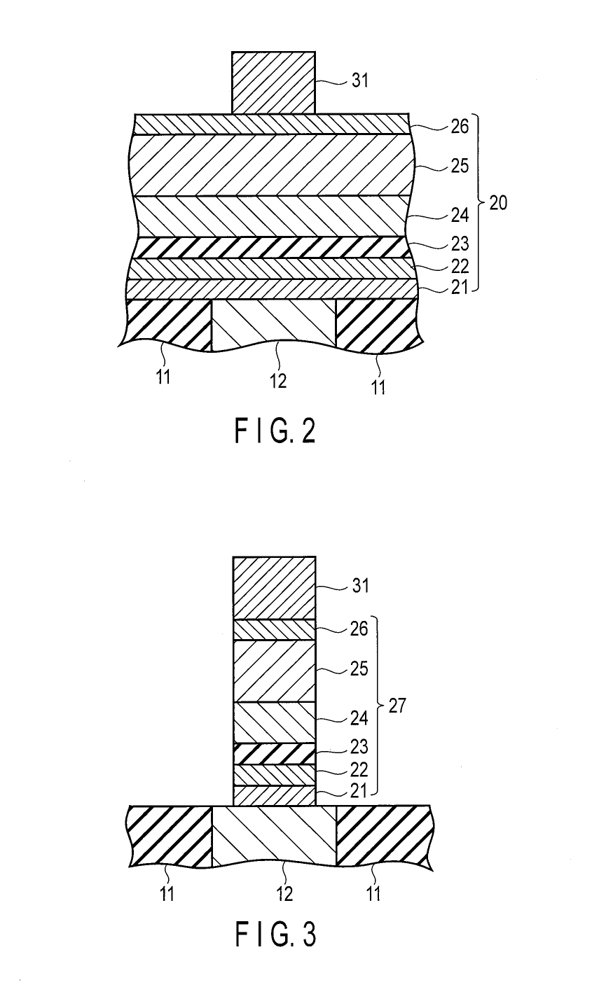

FIGS. 2 to 5 are schematic cross-sectional views showing the method of manufacturing the magnetic memory device of the first embodiment. The manufacturing method of the first embodiment is employed in the apparatus shown in FIG. 1. Further, the manufacturing method of the first embodiment is applied to the manufacture of a magnetic memory device including a magnetoresistive effect element (MTJ element).

Firstly, the process step shown in FIG. 2 is executed. In the step of FIG. 2, a stacked film 20 including magnetic layers is formed on an underlying region including an interlayer insulating film 11 and a lower electrode 12. The underlying region also contains a semiconductor substrate, transistors, wiring, etc. The stacked film 20 comprises an under layer 21, a storage layer (first magnetic layer) 22, a tunnel barrier layer (nonmagnetic layer) 23, a reference layer (second magnetic layer) 24, a shift cancelling layer 25 and a cap layer 26.

The under layer 21 is formed of, for example, Hf, AlN or TaAlN. The storage layer 22 is formed of, for example, CoFeB. The tunnel barrier layer 23 is formed of, for example, MgO or AlO. The reference layer 24 is formed of, for example, CoPt, CoMn or (CoPd+CoFeB). The shift cancelling layer 25 is formed of, for example, CoPt, CoMn or CoPd. The cap layer 26 is formed of, for example, Pt, W, Ta or Ru.

After forming the above-mentioned stacked film 20, a hard mask 31 is formed on the cap layer 26. The hard mask is formed of, for example, W, Ta, TaN, Ti, TiN or C (diamond-like carbon or graphite carbon).

Subsequently, the process step shown in FIG. 3 is executed. In the step of FIG. 3, the substrate shown in FIG. 2 is transferred to the etching chamber 101, wherein at least a part of the stacked film 20 is etched to form a columnar structure 27. In the first embodiment, all layers included in the stacked film 20 are etched. More specifically, the cap layer 26, the shift cancelling layer 25, the reference layer 24, the tunnel barrier layer 23, the storage layer 22 and the under layer 21 are etched by RIE, using the hard mask 31 as a mask. The RIE is performed using an etching gas containing a halogen element, such as chlorine. The etching gas is supplied from the etching gas supply section 111 to the etching chamber 101.

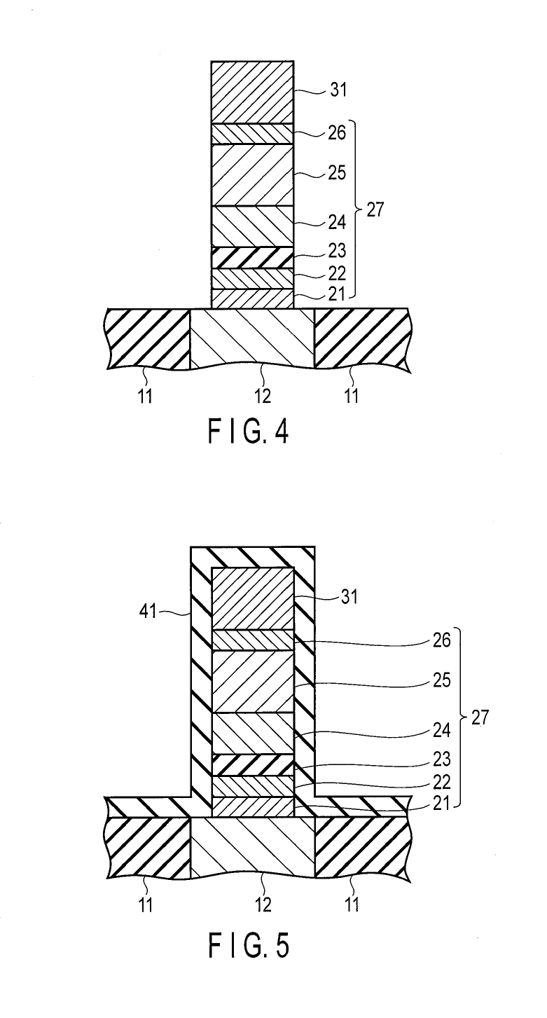

After that, the process step shown in FIG. 4 is executed. In the step of FIG. 4, the substrate shown in FIG. 3 is transferred to the surface treatment chamber 103 via the transfer chamber 105. In the surface treatment chamber 103, a surface treatment is performed on the side surface of the columnar structure 27 using a surface treatment gas containing a predetermined element and hydrogen. The surface treatment is performed with the substrate heated. Namely, the heated columnar structure 27 is subjected to the surface treatment. The surface treatment gas is supplied from the surface treatment gas supply section 113 to the surface treatment chamber 103.

The surface treatment gas includes a gas containing a predetermined element, and hydrogen gas. The predetermined element is selected from the group consisting of silicon (Si), germanium (Ge), arsenic (As), boron (B), aluminum (Al) and tin (Sn). More specifically, the surface treatment gas contains at least one of silane (SiH₄), disilane (Si₂H₆), germane (GeH₄), arsine (AsH₃), diborane (B₂H₆), alane (AlH₃) and stannane (SnH₄).

In the first embodiment, silane (SiH₄) gas and hydrogen (H₂) gas is used as the surface treatment gas. In this case, the flow rate of the hydrogen gas is set greater than that of the silane gas. More specifically, the total flow rate is set to 3000 sccm, and the ratio of the silane gas flow rate to the total flow rate is set to 2% to 40%. The pressure of this gas mixture is set to 2 mT to 5 T. The treatment temperature (heating temperature) is set to 100° C. to 350° C. Further, the surface treatment may be performed in a plasma atmosphere. A microwave of 2.45 GHz is used as a plasma source, and the power of the plasma source is set to 300 W to 5 kW.

A description will be made on the surface treatment.

Halogen element contained in the etching gas is stuck to the side surface of the columnar structure 27 shown in FIG. 3. To eliminate the halogen element, it is effective to do it in an atmosphere of hydrogen gas. By treating the structure in the atmosphere of hydrogen gas, the halogen element is bonded to hydrogen to thereby produce halogen acid (e.g., HCl), with the result that the halogen element is eliminated. However, hydrogen is also bonded to a metal element contained in the columnar structure 27, whereby the metal element may be separated from the columnar structure 27.

To avoid this problem, the first embodiment uses, for the surface treatment, a surface treatment gas containing a predetermined element and hydrogen. When a surface treatment is performed using this surface treatment gas, the predetermined element is bonded to the metal element in the columnar structure 27. For instance, when a surface treatment gas containing SiH₄ gas and H₂ gas is used, the metal element in the columnar structure 27 is bonded to silicon (Si). As a result, bonding of the metal element in the columnar structure 27 to hydrogen is suppressed to thereby prevent separation of the metal element. Further, the halogen element stuck to the side surface of the columnar structure 27 can be eliminated by hydrogen.

Thereafter, the process step shown in FIG. 5 is executed. In the step of FIG. 5, the substrate shown in FIG. 4 is transferred to the deposition chamber 104 via the transfer chamber 105. In the deposition chamber 104, a protective insulation film 41 is formed on the exposed surfaces of the substrate including the treated side surface of the columnar structure 27. A deposition gas is supplied from the deposition gas supply section 114 to the deposition chamber 104. By this step, the columnar structure 27 and the hard mask 31 are covered with the protective insulation film 41. As the protective insulation film 41, a silicon nitride (SiN) film formed by CVD is used.

As described above, a magnetoresistive effect element (MTJ element) covered with the protective insulation film 41 is obtained. The magnetoresistive effect element comprises the storage layer (first magnetic layer) 22, the shift cancelling layer (magnetic layer) 25, the reference layer (second magnetic layer) 24 provided between the storage layer 22 and the shift cancelling layer 25, and the tunnel barrier layer (nonmagnetic layer) 23 provided between the storage layer 22 and the reference layer 24. The storage layer 22 has variable magnetization, and the reference layer 24 and the shift cancelling layer 25 have fixed magnetization.

The other steps including a wiring step, which are not shown, are executed later to produce the magnetic memory device.

As described above, in the first embodiment, a surface treatment using a surface treatment gas containing a predetermined element and hydrogen is executed on the side surface of the columnar structure 27. By virtue of the surface treatment using such a surface treatment gas, the halogen element stuck to the columnar structure 27 can be eliminated by hydrogen, and at the same time, the metal element contained in the columnar structure 27 is bonded to the predetermined element to thereby prevent separation of metal element from the columnar structure 27. This enables the side surface of the columnar structure 27 to be set in an appropriate state.

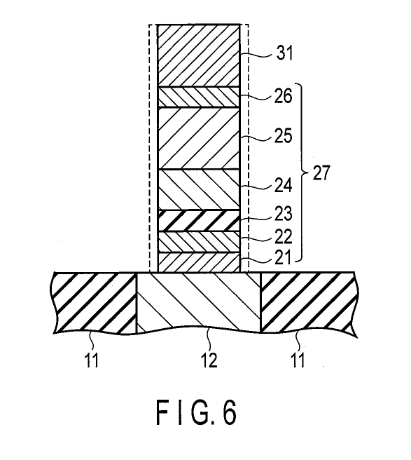

FIG. 6 is a schematic cross-sectional view showing a part of a method of manufacturing a magnetic memory device according to a modification of the first embodiment.

In this modification, the treated side surface of the columnar structure 27 is etched and retreated after the step of FIG. 4. More specifically, the side surface of the columnar structure 27 is thinned by sputtering. After that, the protective film 41 is formed as in the step of FIG. 5.

The side surface of the columnar structure 27 is damaged by the etching. Further, as aforementioned, the side surface of the columnar structure 27 includes silicon-bonded layers. These degraded surfaces are eliminated by the thinning of the side surface, with the result that the side surface of the columnar structure 27 can be set in a more appropriate state.

Although the first embodiment employs RIE for the etching step of FIG. 3, IBE may be used for this purpose, instead of RIE. In this case, etching is performed in the etching chamber 102 for IBE.

When etching is performed by IBE, an etching gas containing a halogen element or containing no halogen element may be used. For instance, argon (Ar) gas is used as the etching gas. Also in this case, the surface treatment can be performed using the above-mentioned surface treatment gas. Namely, also in this case, the metal element contained in the columnar structure 27 is bonded to the predetermined element to thereby prevent separation of the metal element.

### Second Embodiment

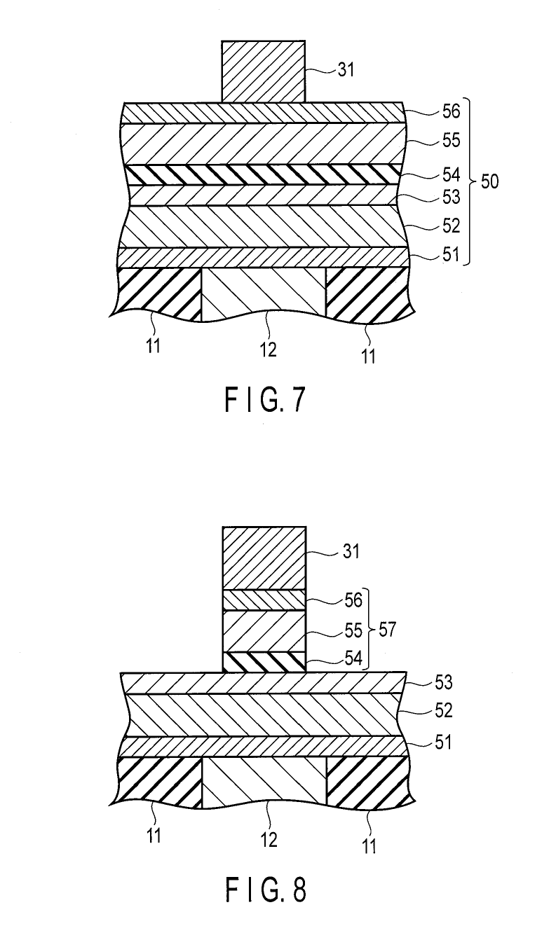

FIGS. 7 to 12 are schematic cross-sectional views showing a method of manufacturing a magnetic memory device according to a second embodiment. This manufacturing method is also employed in the apparatus shown in FIG. 1. Further, this method is also applied to manufacture a magnetic memory device including a magnetoresistive effect element. Since the second embodiment is similar to the first embodiment in basic matters, the matters already described in the first embodiment will not be described again.

Firstly, the process step shown in FIG. 7 is executed. In the step of FIG. 7, a stacked film 50 including magnetic layers is formed on an underlying region including an interlayer insulating film 11 and a lower electrode 12. The stacked film 50 comprises an under layer 51, a shift cancelling layer 52, a storage layer (first magnetic layer) 53, a tunnel barrier layer (nonmagnetic layer) 54, a reference layer (second magnetic layer) 55, and a cap layer 56. The materials of these layers are similar to those in the first embodiment.

After forming the above-mentioned stacked film 50, a hard mask 31 is formed on the cap layer 56. The hard mask is formed of the same material as in the first embodiment.

Subsequently, the process step shown in FIG. 8 is executed. In the step of FIG. 8, the substrate shown in FIG. 7 is transferred to the etching chamber 101, whereby a part of the stacked film 50 is etched to form a columnar structure 57. More specifically, the cap layer 56, the reference layer 55 and the tunnel barrier layer 54 are etched by RIE, using the hard mask 31 as a mask. The etching is performed using an etching gas containing a halogen element, such as chlorine.

Thereafter, the etched substrate is transferred to the surface treatment chamber 103 via the transfer chamber 105. In the surface treatment chamber 103, a surface treatment is performed on the side surface of the columnar structure 57 using a surface treatment gas containing a predetermined element and hydrogen. In this treatment, the same surface treatment gas and the surface treatment method as those of the first embodiment are employed.

In the second embodiment, the halogen element stuck to the side surface of the columnar structure 57 can be eliminated and separation of the metal element contained in the columnar structure 57 can be prevented, as in the first embodiment.

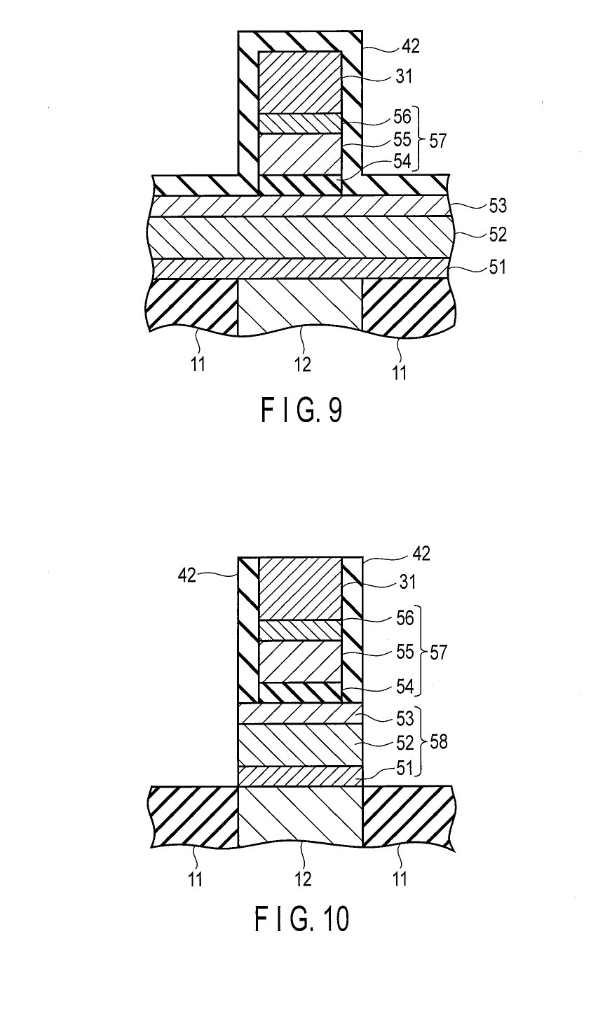

Thereafter, the process step shown in FIG. 9 is executed. In the step of FIG. 9, the surface-treated substrate is transferred to the deposition chamber 104 via the transfer chamber 105. In the deposition chamber 104, a protective insulation film 42 is formed on the exposed surfaces of the substrate including the treated side surface of the columnar structure 57. By this step, the columnar structure 57 and the hard mask 31 are covered with the protective insulation film 42. As the protective insulation film 42, a silicon nitride (SiN) film formed by CVD is used.

Subsequently, the process step shown in FIG. 10 is executed. In the step of FIG. 10, the substrate shown in FIG. 9 is transferred to the etching chamber 101 via the transfer chamber 105. In the etching chamber 101, the protective insulation film 42 and the stacked film (the under layer 51, the shift cancelling layer 52 and the storage layer 53) are etched by RIE, using an etching gas containing a halogen element, such as chlorine. As a result, a columnar structure 58 including the under layer 51, the shift cancelling layer 52 and the storage layer 53 is formed. The protective insulation film 42 is left on the side surfaces of the columnar structure 57 and the hard mask 31.

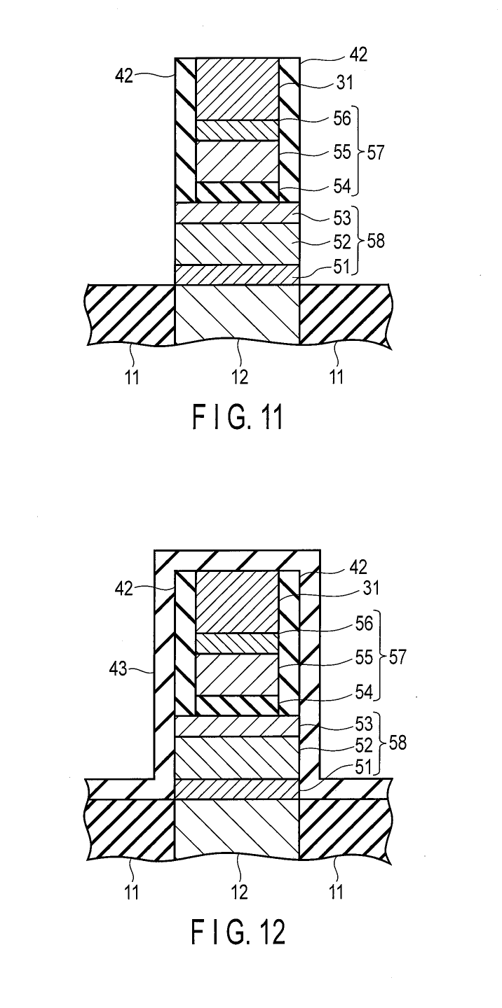

After that, the process step shown in FIG. 11 is executed. In the step of FIG. 11, the substrate shown in FIG. 10 is transferred to the surface treatment chamber 103 via the transfer chamber 105. In the surface treatment chamber 103, a surface treatment is performed on the side surface of the columnar structure 58, using a surface treatment gas containing a predetermined element and hydrogen. In this treatment, the same surface treatment gas and surface treatment method as those of the first embodiment are employed.

The halogen element stuck to the side surface of the columnar structure 58 can be eliminated and separation of the metal element contained in the columnar structure 58 can be prevented, as in the first embodiment.

After that, the process step shown in FIG. 12 is executed. In the step of FIG. 12, the substrate shown in FIG. 11 is transferred to the deposition chamber 104 via the transfer chamber 105. In the deposition chamber 104, a protective insulation film 43 is formed on the exposed surfaces of the substrate including the treated side surface of the columnar structure 58. By this step, the structure including the columnar structure 58, the columnar structure 57, the hard mask 31 and the protective insulation film 42, is covered with the protective insulation film 43. As the protective insulation film 43, a silicon nitride (SiN) film formed by CVD is used.

As a result, a magnetoresistive effect element (MTJ element) covered with the protective insulation films 42 and 43 is obtained.

The other steps including a wiring step, which are not shown, are executed later to produce the magnetic memory device.

As described above, also in the second embodiment, a surface treatment using a surface treatment gas containing a predetermined element and hydrogen is executed on the side surfaces of the columnar structures 57 and 58. This enables the side surfaces of the columnar structures 57 and 58 to be set in appropriate states, as in the first embodiment.

Also in the second embodiment, the treated side surface of the columnar structure 57 may be thinned as in the modification of the first embodiment.

Similarly, the treated side surface of the columnar structure 58 may be thinned.

In addition, although in the second embodiment, the etching process shown in FIG. 8 is realized by RIE, it may be done by IBE. Similarly, the etching process shown in FIG. 10 may also be done by IBE.

When etching is performed by IBE, an etching gas containing a halogen element or containing no halogen element may be used. For instance, argon (Ar) gas is used as the etching gas. Also in this case, the surface treatment can be performed using the above-mentioned surface treatment gas.

### Third Embodiment

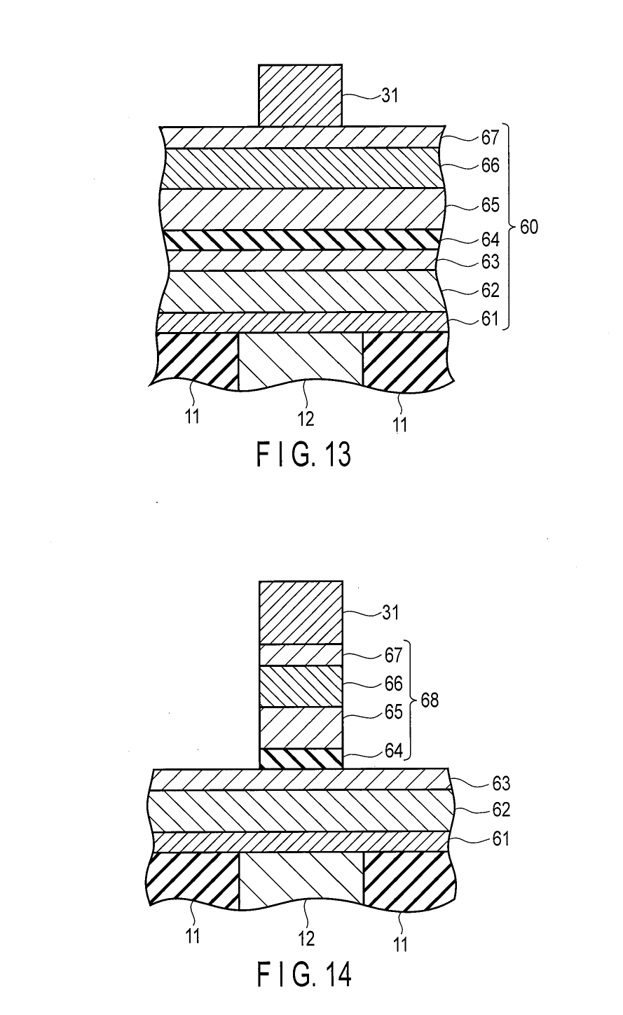

FIGS. 13 to 18 are schematic cross-sectional views showing a method of manufacturing a magnetic memory device according to a third embodiment. This manufacturing method is also employed in the apparatus shown in FIG. 1. Further, this method is also applied to manufacture a magnetic memory device including a magnetoresistive effect element. Since the third embodiment is similar to the first or second embodiment in basic matters, the matters already described in the first or second embodiment will not be described again.

Firstly, the process step shown in FIG. 13 is executed. In the step of FIG. 13, a stacked film 60 including magnetic layers is formed on an underlying region including an interlayer insulating film 11 and a lower electrode 12. The stacked film 60 comprises an under layer 61, a shift cancelling layer 62, a storage layer (first magnetic layer) 63, a tunnel barrier layer (nonmagnetic layer) 64, a reference layer (second magnetic layer) 65, a shift cancelling layer 66 and a cap layer 67. The materials of these layers are similar to those in the first embodiment.

After forming the above-mentioned stacked film 60, a hard mask 31 is formed on the cap layer 67. The hard mask 31 is formed of the same material as in the first embodiment.

Subsequently, the process step shown in FIG. 14 is executed. In the step of FIG. 14, the substrate shown in FIG. 13 is transferred to the etching chamber 101, whereby a part of the stacked film 60 is etched to form a columnar structure 68. More specifically, the cap layer 67, the shift cancelling layer 66, the reference layer 65 and the tunnel barrier layer 64 are etched by RIE, using the hard mask 31 as a mask. The etching is performed using an etching gas containing a halogen element, such as chlorine.

The etched substrate is transferred to the surface treatment chamber 103 via the transfer chamber 105. In the surface treatment chamber 103, a surface treatment is performed on the side surface of the columnar structure 68 using a surface treatment gas containing a predetermined element and hydrogen. In this treatment, the same surface treatment gas and surface treatment method as those of the first embodiment are employed.

In the third embodiment, the halogen element stuck to the side surface of the columnar structure 68 can be eliminated and separation of the metal element contained in the columnar structure 68 can be prevented, as in the first embodiment.

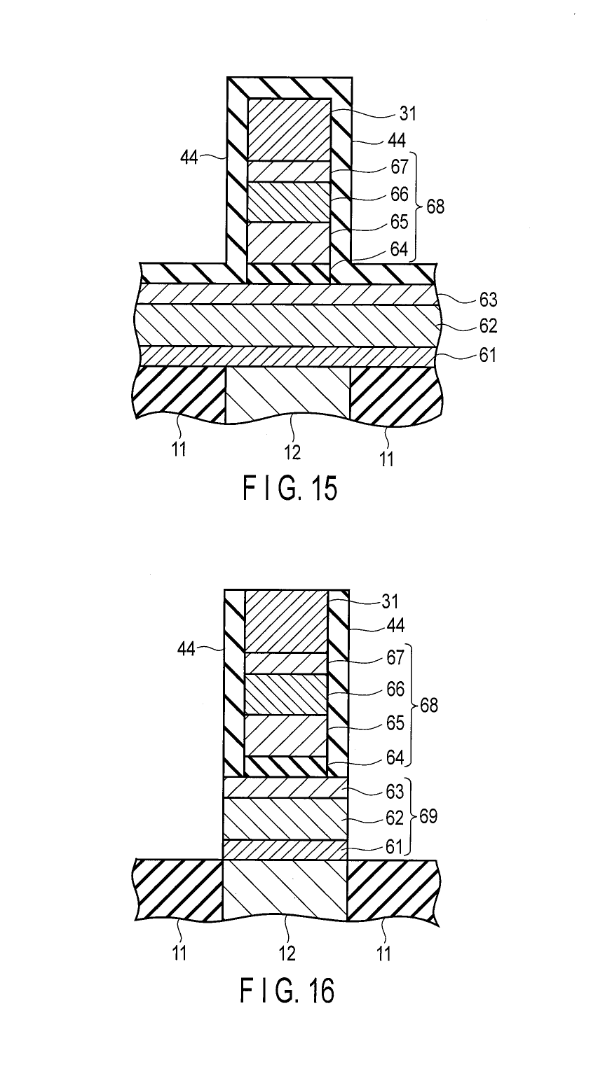

Subsequently, the process step shown in FIG. 15 is executed. In the step of FIG. 15, the surface-treated substrate is transferred to the deposition chamber 104 via the transfer chamber 105. In the deposition chamber 104, a protective insulation film 44 is formed on the exposed surfaces of the substrate including the treated side surface of the columnar structure 68. By this step, the columnar structure 68 and the hard mask 31 are covered with the protective insulation film 44. As the protective insulation film 44, a silicon nitride (SiN) film formed by CVD is used.

After that, the process step shown in FIG. 16 is executed. In the step of FIG. 16, the substrate shown in FIG. 15 is transferred to the etching chamber 101 via the transfer chamber 105. In the etching chamber 101, the protective insulation film 44 and the stacked film (the under layer 61, the shift cancelling layer 62 and the storage layer 63) are etched by RIE, using an etching gas containing a halogen element, such as chlorine. As a result, a columnar structure 69 including the under layer 61, the shift cancelling layer 62 and the storage layer 63 is formed. The protective insulation film 44 is left on the side surface of the columnar structure 68.

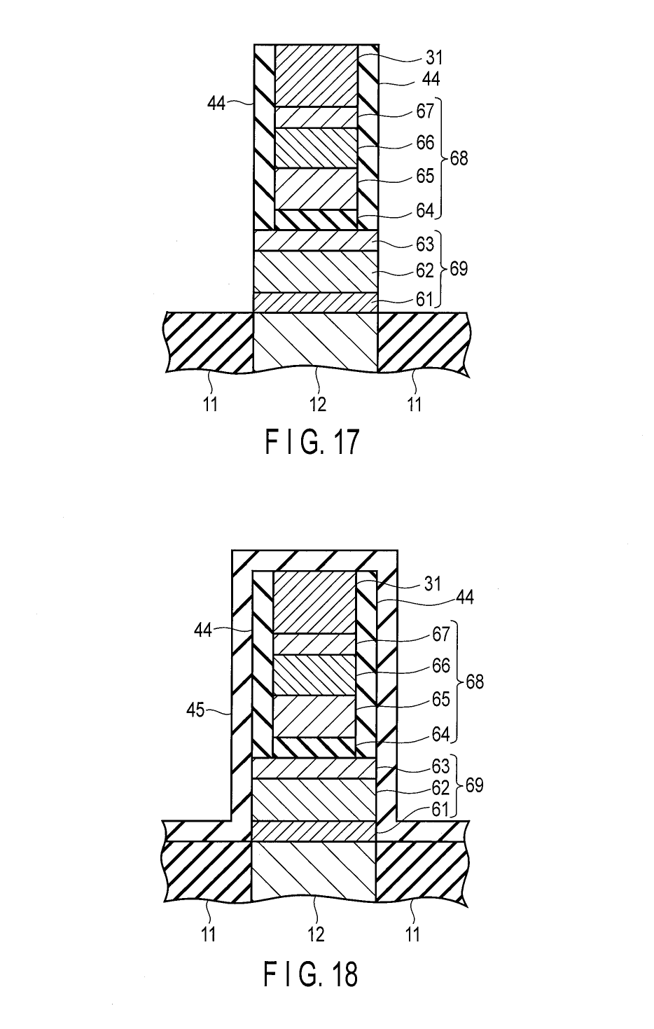

After that, the process step shown in FIG. 17 is executed. In the step of FIG. 17, the substrate shown in FIG. 16 is transferred to the surface treatment chamber 103 via the transfer chamber 105. In the surface treatment chamber 103, a surface treatment is performed on the side surface of the columnar structure 69, using a surface treatment gas containing a predetermined element and hydrogen. In this treatment, the same surface treatment gas and surface treatment method as those of the first embodiment are employed.

In the third embodiment, the halogen element stuck to the side surface of the columnar structure 69 can be eliminated and separation of the metal element contained in the columnar structure 69 can be prevented, as in the first embodiment.

Thereafter, the process step shown in FIG. 18 is executed. In the step of FIG. 18, the substrate shown in FIG. 17 is transferred to the deposition chamber 104 via the transfer chamber 105. In the deposition chamber 104, a protective insulation film 45 is formed on the exposed surfaces of the substrate including the treated side surface of the columnar structure 69. By this step, the structure including the columnar structures 68 and 69, the hard mask 31 and the protective insulation film 44 is covered with the protective insulation film 45. As the protective insulation film 45, a silicon nitride (SiN) film formed by CVD is used.

As described above, a magnetoresistive effect element (MTJ element) covered with the protective insulation films 44 and 45 is obtained.

The other steps including a wiring step, which are not shown, are executed later to produce the magnetic memory device.

As described above, also in the third embodiment, a surface treatment using a surface treatment gas containing a predetermined element and hydrogen is executed on the side surfaces of the columnar structures 68 and 69. This enables the side surfaces of the columnar structures 68 and 69 to be set in appropriate states, as in the first embodiment.

Also in the third embodiment, the treated side surface of the columnar structure 68 may be thinned as in the modification of the first embodiment. Similarly, the treated side surface of the columnar structure 69 may be thinned.

In addition, although in the third embodiment, the etching process shown in FIG. 14 is realized by RIE, it may be done by IBE. Similarly, the etching process shown in FIG. 16 may also be done by IBE.

When etching is performed by IBE, an etching gas containing a halogen element or containing no halogen element may be used. For instance, argon (Ar) gas is used as the etching gas. Also in this case, the surface treatment can be performed using the above-mentioned surface treatment gas.

In each of the above-described embodiments, the halogen element contained in the etching gas may be fluorine, bromine or iodine, as well as chlorine.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a magnetic memory device, comprising:
etching at least a part of a stacked film including a magnetic layer, to form a columnar structure; and
performing a surface treatment on a side surface of the columnar structure, using a surface treatment gas containing a predetermined element and hydrogen.

2. The method of claim 1, wherein performing the surface treatment includes bonding the predetermined element to a metal element contained in the columnar structure.

3. The method of claim 1, wherein the surface treatment gas includes a gas containing the predetermined element, and hydrogen gas.

4. The method of claim 1, wherein the predetermined element is selected from silicon (Si), germanium (Ge), arsenic (As), boron (B), aluminum (Al) and tin (Sn).

5. The method of claim 1, wherein the surface treatment gas contains at least one of silane (SiH₄), disilane (Si₂H₆), germane (GeH₄), arsine (AsH₃), diborane (B₂H₆), alane (AlH₃) and stannane (SnH₄).

6. The method of claim 1, wherein the surface treatment is performed, with the columnar structure heated.

7. The method of claim 1, wherein etching at least the part of the stacked film is performed using an etching gas containing a halogen element.

8. The method of claim 1, wherein etching at least the part of the stacked film is performed using RTE.

9. The method of claim 1, wherein etching at least the part of the stacked film is performed using IBE.

10. The method of claim 1, further comprising forming an insulating film on the treated side surface of the columnar structure.

11. The method of claim 1, further comprising etching the treated side surface of the columnar structure to retreat the treated side surface.

12. The method of claim 11, wherein etching the treated side surface of the columnar structure includes sputtering the treated side surface of the columnar structure.

13. The method of claim 1, wherein the stacked film includes a first magnetic layer, a second magnetic layer, and a nonmagnetic layer interposed between the first and second magnetic layers.

14. The method of claim 13, wherein the first magnetic layer is a storage layer, and the second magnetic layer is a reference layer.

15. An apparatus for manufacturing a magnetic memory device, comprising:
an etching chamber used to etch at least a part of a stacked film including a magnetic layer, to form a columnar structure; and
a treatment chamber used to perform a treatment on the columnar structure, using a treatment gas containing a predetermined element and hydrogen.

16. The apparatus of claim 15, further comprising a treatment gas supply section configured to supply the treatment gas to the treatment chamber.

17. The apparatus of claim 15, further comprising a deposition chamber used to form an insulating film on the treated columnar structure.

18. The apparatus of claim 15, wherein the treatment gas includes a gas containing the predetermined element, and hydrogen gas.

19. The apparatus of claim 15, wherein the predetermined element is selected from silicon (Si), germanium (Ge), arsenic (As), boron (B), aluminum (Al) and tin (Sn).

20. The apparatus of claim 15, wherein the treatment gas contains at least one of silane (SiH₄), disilane (Si₂H₆), germane (GeH₄), arsine (AsH₃), diborane (B₂H₆), alane (AlH₃) and stannane (SnH₄).
